(19) United States
(12) Patent Application Publication
(10) Pub. No.: US 2006/0148182 A1
(43) Pub. Date: Jul. 6, 2006

(54) Quantum well transistor using high dielectric constant dielectric layer

(76) Inventors: Suman Datta, Beaverton, OR (US); Justin K. Brask, Portland, OR (US); Jack Kavalieros, Portland, OR (US); Matthew V. Metz, Hillsboro, OR (US); Mark L. Doczy, Beaverton, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 11/028,378

(22) Filed: Jan. 3, 2005

(51) Int. Cl. H01L 21/336

(52) U.S. Cl. 438/289

(57) ABSTRACT

A quantum well transistor or high electron mobility transistor may be formed using a replacement metal gate process. A dummy gate electrode may be used to define sidewall spacers and source drain contact metallizations. The dummy gate electrode may be removed and the remaining structure used as a mask to etch a doped layer to form sources and drains self-aligned to said opening. A high dielectric constant material may coat the sides of said opening and then a metal gate electrode may be deposited. As a result, the sources and drains are self-aligned to the metal gate electrode. In addition, the metal gate electrode is isolated from an underlying barrier layer by the high dielectric constant material.

### BACKGROUND

This invention relates generally to the formation of quantum well transistors.

A quantum well is a potential well that confines particles in a dimension forcing them to occupy a planar region. A first material, sandwiched between two layers of a material with a wider band gap than the first material, may form a quantum well. Quantum well or high electron mobility transistors (HEMTs) are field effect transistors with a junction between two materials with different band gaps as the channel. The junction may exhibit very low resistance or high electron mobility. A voltage applied to the gate may alter the conductivity of the junction.

Quantum well transistors may be prone to high gate leakage and parasitic series resistance. Particularly, quantum well transistors using elements from columns III through V of the periodic table may be prone to such problems. Examples of such materials include indium gallium arsenide/indium aluminum arsenide and indium antimony/aluminum indium antimony.

In current state of the art quantum well transistors, a direct Schottky metal gate may be deposited on a barrier layer to form the Schottky junction which may be prone to high gate leakage. Also, the source and drain regions may be patterned and source and drain contact metallization completed before gate patterning. The gate patterning is done as the last step in the process, which may result in non-self-aligned source drain regions. Such non-self-aligned source drain regions may be prone to parasitic series resistance. Devices with parasitic series resistance may exhibit poor performance.

Thus, there is a need for better ways to make quantum well transistors.

### BRIEF DESCRIPTION OF THE DRAWINGS

FIG. 1 is an enlarged, cross-sectional view of one embodiment of the present invention;

FIG. 2 is an enlarged, cross-sectional view of the embodiment shown in FIG. 1 at an early stage of manufacture in accordance with one embodiment of the present invention;

FIG. 3 is an enlarged, cross-sectional view of the embodiment shown in FIG. 2 after subsequent processing in accordance with one embodiment of the present invention;

FIG. 4 is an enlarged, cross-sectional view corresponding to FIG. 3 after subsequent processing in accordance with one embodiment of the present invention;

FIG. 5 is an enlarged, cross-sectional view corresponding to FIG. 4 after subsequent processing in accordance with one embodiment of the present invention;

FIG. 6 is an enlarged, cross-sectional view corresponding to FIG. 5 after subsequent processing in accordance with one embodiment of the present invention;

FIG. 7 is an enlarged, cross-sectional view corresponding to FIG. 6 after subsequent processing in accordance with one embodiment of the present invention;

FIG. 8 is an enlarged, cross-sectional view corresponding to FIG. 7 after subsequent processing in accordance with another embodiment of the present invention;

FIG. 9 is an enlarged, cross-sectional view corresponding to FIG. 8 after subsequent processing in accordance with a depletion mode embodiment of the present invention; and

FIG. 10 is an enlarged, cross-sectional view corresponding to FIG. 7 after subsequent processing in accordance with an enhancement mode embodiment of the present invention;

### DETAILED DESCRIPTION

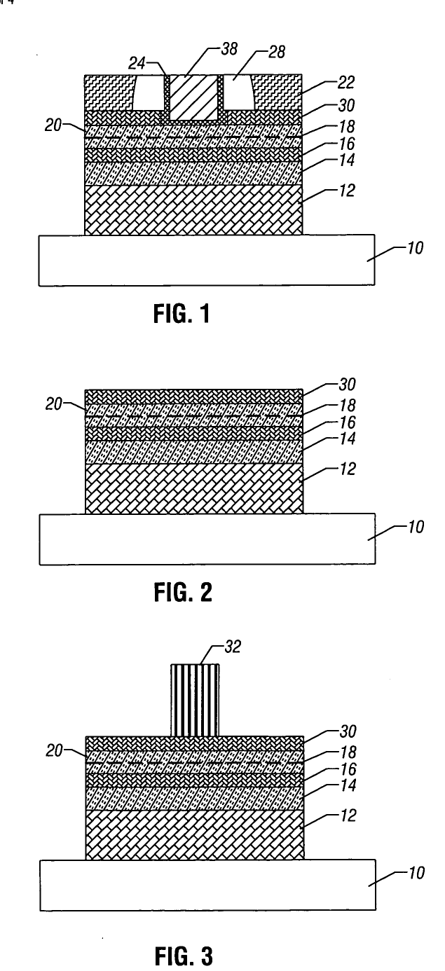

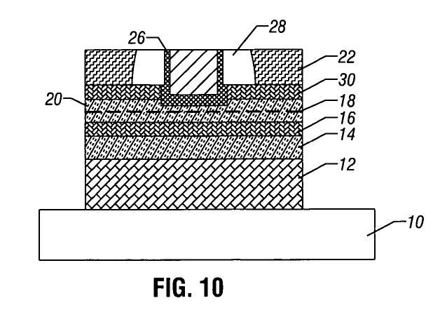

Referring to FIGS. 1 and 10, a depletion (FIG. 1) or enhancement mode (FIG. 10) self-aligned source drain quantum well transistor may be formed with a high dielectric constant dielectric layer 24 and a metal gate electrode 38 that acts as a Schottky gate metal. As used herein “high dielectric constant” refers to dielectrics having dielectric constants of 10 or greater.

Over a silicon substrate 10 may be an accommodation layer 12. The accommodation layer 12 may be AlInSb with 15% aluminum in one embodiment. Over a silicon substrate 10, a germanium layer (not shown) may be included under the layer 12 as well. The accommodation layer 12 functions to accommodate for the lattice mismatch problem and to confine dislocations or defects in that layer 12.

Over the accommodation layer 12 may be formed a lower barrier layer 14 in accordance with one embodiment of the present invention. The lower barrier layer 14 may, for example, be formed of aluminum indium antimonide or indium aluminum arsenide, as two examples. The lower barrier layer 14 may be formed of a higher band gap material than the overlying quantum well 16.

Over the lower barrier layer 14 is formed the undoped quantum well 16. In one embodiment, the undoped quantum well 16 may be formed of indium antimonide or indium gallium arsenide, as two examples.

Next, the upper barrier layer 20 may be formed. The upper barrier layer 20 may be formed of the same or different materials as the lower barrier layer 14. The upper barrier layer 20 may include a delta doped donor layer 18. The delta doping may be done using silicon or tellurium, as two examples. The doped donor layer 18 supplies carriers to the quantum well 16 for transport. The doped donor layer 18 is formed by allowing Te or Si dopants to flow into the MBE (Molecular Beam Epitaxy) chamber in a controlled fashion from a solid source.

Thus, the quantum well 16 is sandwiched between the upper and lower barrier layers 20 and 14. The upper barrier layer 20 may be an electron supplying layer whose thickness will determine the threshold voltage of the transistor, along with the workfunction of the Schottky metal layer forming the gate electrode 38.

The metal gate electrode 38 may be formed over a high dielectric constant dielectric material 26. The material 26 brackets the metal gate electrode 38 on three sides. The high dielectric constant layer 26 may, in turn, be bracketed by a self-aligned source drain contact metallization 22 and a spacer layer 28.

Fabrication of the depletion mode transistor, shown in FIG. 1, and the enhancement mode transistor of FIG. 10 may begin, as shown in FIG. 2, by forming the structure up to and including an n+ doped layer 30. The layer 30 may include an indium antimonide or indium gallium arsenide doped with Te and Si impurities. The layer 30 may be highly doped to later form the source drain regions in the finished transistor.

The multilayer epitaxial substrate 10 may be grown using molecular beam epitaxy or metal organic chemical vapor deposition, as two examples.

Referring to FIG. 3, a dummy gate 32 may be formed over the n+ doped layer 30 in accordance with one embodiment of the present invention. It may be formed after patterning and etch out of nitride, carbide, or oxide films (not shown). Advantageously, these films may be formed by low temperature deposition to preserve the integrity of the epitaxial layer structure. The dummy gate 32 may, for example, be formed of silicon nitride or metal. The dummy gate 32 may be formed by patterning through either lithography and etching, in the case of a silicon nitride dummy gate 32, or through evaporation and liftoff in the case of a metal gate 32, such as an aluminum metal dummy gate.

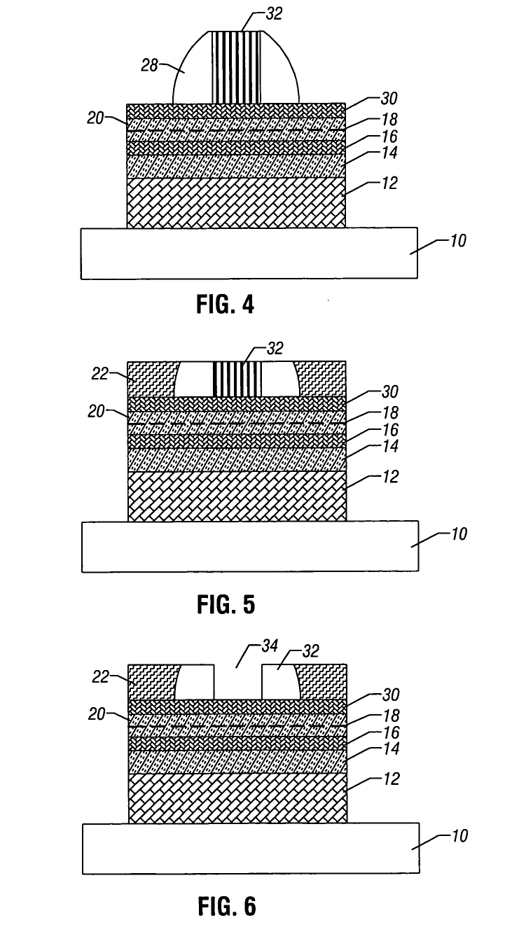

Referring next to FIG. 4, low temperature silicon oxide, nitride or carbide spacers 28 may be formed that bracket the dummy gate 32. The spacers 28 may be formed by a low temperature deposition technique, followed by anisotropic etching.

Turning next to FIG. 5, the self-aligned source drain contact metallizations 22 may be formed by electron beam evaporation or reactive sputtering, either followed by a chemical mechanical planarization process, to create self-aligned contacts to the yet to be formed source drain regions in the layer 30. The source drain contact metallization 22 may, for example, be formed of titanium or gold.

Then, as shown in FIG. 6, the dummy gate 32 may be selectively etched out using a wet etch. As a result, an opening 34 is formed. A metal dummy gate removal process may, for example, include a wet etch using phosphoric acid etch. For a nitride dummy gate, hydrochloric acid may be used. For a silicon dioxide dummy gate a hydrofluoric acid etch can be used. The wet etch process is selective to the n+ doped layer 30.

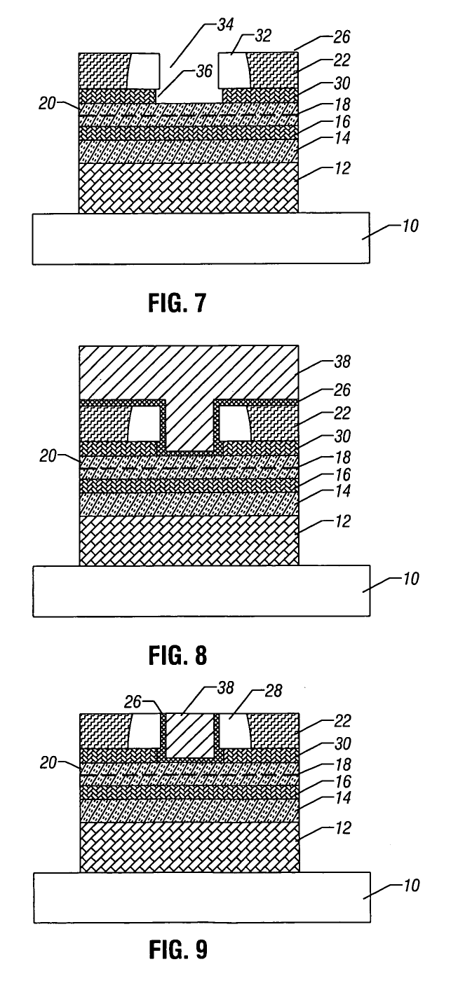

Then, as shown in FIG. 7 for a depletion mode device, a selective etch out of the n+ doped layer 30 may be achieved to form an inverted T-shaped opening having wings 36 and a base 34. Dry or wet etching may be utilized to form the wings 36. For example, the n+ doped layer 30 is selectively removed using a wet etch process such as citric acid plus peroxide.

Atomic layer deposition of the high dielectric constant material 26 may be followed by electron beam evaporation or sputtering of a metal gate electrode 38. The gate electrode 38 may, for example, be platinum, tungsten, palladium, or molybdenum, to mention a few examples. The high dielectric constant dielectric 26 may, for example, be hafnium dioxide or zirconium dioxide, as two examples. A low temperature deposition process may be utilized with an organic precursor (such as alkoxide precursor for hafnium dioxide deposition).

The structure shown in FIG. 8 may then be subjected to a chemical mechanical polish of the metal gate electrode 38 and the high dielectric constant dielectric 26 to achieve the depletion mode structure shown in FIG. 9.

Right after the n+ doped layer 30 etch out to form the opening 34 including wings 36 and base 34, as shown in FIG. 7, a further recess etch may be done through the electron supplying barrier layer 20, stopping just above the delta doped layer 18 to make an enhancement mode device as shown in FIG. 10. A time drive etch (not shown in FIG. 7) may partially recess into the electron supplying barrier layer 20 in FIG. 7 and under the spacers 28, to increase the threshold voltage of the transistor and to form an enhancement mode device.

The device layer structure survives the high dielectric constant deposition process. This may be followed by sputter deposition or electron beam deposition of the Schottky gate electrode 38. The gate electrode 38 workfunction may be chosen to be as high as possible to create an enhancement mode device.

Some embodiments of the present invention may achieve lower gate leakage from the incorporation of a high dielectric constant dielectric 20 in between the Schottky gate metal of the electrode 38 and the semiconductor barrier layer 20. Lower parasitic series resistance may result, in some embodiments, from the highly doped source drain region self-aligned to the gate. In some embodiments, the recess etch of the electron supplying barrier layer 20 to the desired thickness forms an enhancement mode quantum well field effect transistor.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a self-aligned source drain in a quantum well transistor.

2. The method of claim 1 including forming a self-aligned source drain from a doped layer, forming an opening in said doped layer, and depositing a gate electrode in said doped layer.

3. The method of claim 2 including depositing a metal gate electrode.

4. The method of claim 3 including using a dummy gate over said doped layer and subsequently removing said dummy gate.

5. The method of claim 4 including using said dummy gate to define a sidewall spacer.

6. The method of claim 5 including using said sidewall spacer to define self-aligned source drain contacts.

7. The method of claim 6 including removing said dummy gate after defining said spacers and said contacts.

8. The method of claim 7 including using said contacts and said spacers as a mask to etch said doped layer and to define a source and drain.

9. The method of claim 8 including etching said doped layer so as to undercut said spacers.

10. The method of claim 9 including depositing a layer in said opening having a dielectric constant greater than 10.

11. The method of claim 10 including forming a metal gate electrode over said dielectric.

12. The method of claim 11 including forming a barrier layer under said gate dielectric.

13. The method of claim 12 including separating said metal gate electrode from said barrier layer by said dielectric.

14. The method of claim 1 including forming a depletion mode transistor by etching through said doped layer.

15. The method of claim 13 including forming an enhancement mode transistor by forming said doped layer over an upper barrier layer and etching into said upper barrier layer such that said gate dielectric extends through said doped layer and into said upper barrier layer.

16. The method of claim 9 including controlling the depth of etching to determine whether an enhancement mode or a depletion mode device is formed.

17. The method of claim 16 including etching through said doped layer and into an underlying barrier layer to form an enhancement device.

18. A method comprising:
forming a quantum well transistor with a barrier layer and a Schottky gate metal and a dielectric, between said gate metal and said barrier layer, having a dielectric constant greater than 10.

19. The method of claim 18 including forming a self-aligned source drain in said quantum well transistor.

20. The method of claim 19 including forming a self-aligned source drain from a doped layer, forming an opening in said doped layer, and depositing a gate electrode in said doped layer.

21. The method of claim 20 including depositing a metal gate electrode.

22. The method of claim 21 including using a dummy gate over said doped layer and subsequently removing said dummy gate.

23. The method of claim 22 including using said dummy gate to define a sidewall spacer.

24. The method of claim 23 including using said sidewall spacer to define self-aligned source drain contacts.

25. The method of claim 24 including removing said dummy gate after defining said spacer and said contacts.

26. The method of claim 25 including using said contacts and said spacer as a mask to etch said doped layer and to define a source and drain.

27. The method of claim 26 including etching said doped layer so as to undercut said spacer.

28. The method of claim 27 including depositing a dielectric in said opening having a dielectric constant greater than 10.

29. The method of claim 28 including forming a metal gate electrode over said dielectric.

30. The method of claim 29 including forming said barrier layer under said dielectric.

31. The method of claim 30 including separating said metal gate electrode from said barrier layer by said dielectric.

32. The method of claim 20 including forming a depletion mode transistor by etching through said doped layer.

33. The method of claim 28 including forming an enhancement mode transistor by forming said doped layer over said barrier layer and etching into said barrier layer such that said dielectric extends through said doped layer and into said barrier layer.

34. The method of claim 27 including controlling the depth of etching to determine whether an enhancement mode or a depletion mode device is formed.

35. The method of claim 34 including etching through said doped layer and into an underlying barrier layer to form an enhancement device.

36. A quantum well transistor comprising:
a first and second barrier layer;
a quantum well layer between said barrier layers;
a gate electrode; and
a source drain self-aligned to said gate electrode.

37. The transistor of claim 36 including sidewall spacers on said gate electrode.

38. The transistor of claim 37 wherein said gate electrode is a metal gate electrode.

39. The transistor of claim 38 including a contact metallization to said source and drain.

40. The transistor of claim 36 including a dielectric between said gate electrode and said first barrier layer, said dielectric having a dielectric constant greater than 10.

41. The transistor of claim 40 wherein said dielectric is U-shaped.

42. A quantum well transistor comprising:
a first and second barrier layer;
a quantum well layer between said barrier layers;
a metal gate electrode; and
a dielectric between said gate electrode and said first barrier layer, said dielectric having a dielectric constant greater than 10.

43. The transistor of claim 42 including a self-aligned source drain.

44. The transistor of claim 42 including sidewall spacers on said gate electrode.

45. The transistor of claim 42 including a contact metallization to said source and drain.

46. The transistor of claim 42 wherein said dielectric is U-shaped.
